(19) United States
(12) Patent Application Publication
(10) Pub. No.: US 2025/0233105 A1
(43) Pub. Date: Jul. 17, 2025

(54) SYSTEM AND METHOD FOR CLEANING SILICON AND HYDROCARBON CONTACT RESIDUE FROM CHIP SURFACES USING ATMOSPHERIC PLASMA

(71) Applicant: Ontos Equipment Systems, Inc., CHESTER, NH (US)

(72) Inventors: DANIEL PASCUAL, WOLCOTT, VT (US); TAYLOR WUNSCH, MORRISVILLE, VT (US); LOGAN HARRIS, MORRISVILLE, VT (US); DAVID MEYER, JEFFERSONVILLE, VT (US)

(73) Assignee: Ontos Equipment Systems, Inc., CHESTER, NH (US)

(21) Appl. No.: 19/096,277

(22) Filed: Mar. 31, 2025

Related U.S. Application Data
(63) Continuation-in-part of application No. 17/085,786, filed on Oct. 30, 2020.
(60) Provisional application No. 63/574,398, filed on Apr. 4, 2024.

(51) Int. Cl. H01L 23/00; C09J 5/00; C09J 7/30

(52) U.S. Cl. CPC H01L 24/80; C09J 5/00; C09J 7/30; C09J 2203/326; C09J 2301/502; H01L 2224/80013; H01L 2224/80894

(57) ABSTRACT

An atmospheric pressure plasma system is used to clean surface contaminants from chip surfaces prior to direct bonding them onto wafers. The surface contaminants include contact residue transferred from common adhesive films and silicone membranes used in semiconductor fabrication and packaging. WCA and FTIR data confirm the transfer of hydrocarbon and silicone contaminant residue that reduce hydrophilicity and surface energy. The atmospheric plasma treatment of the chip surfaces significantly reduces or eliminates these contaminants and results in stronger bonds than the untreated chip surfaces.

### CROSS REFERENCE TO RELATED CO-PENDING APPLICATIONS

This application claims the benefit of U.S. provisional application Ser. No. 63/574,398 filed on Apr. 4, 2024 and entitled “System and method for cleaning silicon and hydrocarbon contact residue from chip surfaces using atmospheric plasma”, which is commonly assigned and the contents of which are expressly incorporated herein by reference.

This application is a continuation in part and claims the benefit of U.S. nonprovisional application Ser. No. 17/085,786 filed on Oct. 30, 2020 and entitled “THERMOCOMPRESSION BONDING WITH PASSIVATED TIN-BASED CONTACTING METAL”, which is commonly assigned and the contents of which are expressly incorporated herein by reference.

### FIELD OF THE INVENTION

The present invention relates to a system and a method for cleaning silicon hydrocarbon contact residue from chip surfaces using atmospheric plasma.

### BACKGROUND OF THE INVENTION

New technologies such as 5G, artificial intelligence (AI), virtual reality (VR) and autonomous vehicles require enormous computing power with processors optimized specifically for each application. These trends are pushing microelectronics towards faster performance, smaller packaging and lower cost requirements. The increased cost and complexity of the 2D device scaling has driven the semiconductor industry towards heterogeneous 3D-IC integration for addressing current and future high-performance demands.

Heterogeneous 3D-IC integration refers to the manufacturing, assembly and packaging of multiple different components or dies 32, 33, 34, 35 with different features, sizes, and materials onto a single device or package 31, as shown in FIG. 1A. A simple chip-handling flow for die-to-wafer (D2W) direct hybrid bonding involves removing singulated chips 32 from a dicing film or a gel pack 20 and moving them onto a wafer 31 where they are direct bonded for heterogeneous integrations, as shown in FIG. 1B.

D2W hybrid bonding provides the benefits of increased yield, and flexibility. The yield is increased because only known good quality dies are used. The method is most flexible because dies of different size can be used. At the same time D2W bonding has a higher risk of die surface contamination from equipment and handling. D2W bonding also has a slower throughput compared to wafer-to-wafer (W2W) bonding.

In some cases, die-to-wafer bonding involves attaching individual dies onto a carrier wafer before integration onto the target wafer. This is because the cleaning and vacuum plasma systems typically require work pieces to be in wafer form, not individual dies. However, the use of carrier wafers introduces additional processing steps and potential contamination issues. The long process time required to pump down and vent vacuum plasma systems also necessitate batch processing for increased throughput.

Accordingly, there is a need for reducing the die surface contamination and increasing the throughput.

### SUMMARY OF THE INVENTION

The present invention relates to a system and a method for cleaning silicon hydrocarbon contact residue from chip surfaces using atmospheric plasma.

In general, in one aspect the invention provides a method of die-to-wafer (D2W) direct hybrid bonding, including the following steps. First removing a singulated die from a support frame. The singulated die is held onto the support frame via an adhesive film or silicone membrane and a bonding surface of the singulated die is contaminated at a molecular level by the adhesive film or silicone membrane. Next, directing plasma-activated radical-enriched gas flow at substantially ambient atmospheric conditions to the contaminated bonding surface of the singulated die. The plasma-activated radical-enriched gas both removes molecular contaminants from the contaminated bonding surface resulting in a clean bonding surface and also passivates the clean bonding surface. Next, directly bonding the clean bonding surface of the singulated die onto a wafer for heterogeneous integration.

Implementations of this aspect of the invention include one or more of the following. The molecular contaminants comprise hydrocarbons or comprise silicones. The plasma-activated radical-enriched gas comprises He and O₂ plasma, or He and H₂ plasma or He and O₂ and H₂ plasma, or helium (He), or nitrogen (N₂), or oxygen (O₂), or Argon (Ar), or helium hydrogen (HeH₂) mix or mixtures thereof. The adhesive film may be a dicing tape, or UV dicing tape. The silicone membrane may be a silicone membrane with tack level 4, or a silicone membrane with tack level 8. The method may further include measuring hydrophilicity and surface energy of the bonding surface via water contact angle (WCA). The method may further include measuring and identifying the molecular contaminants via Fourier transform infrared spectroscopy (FTIR).

In general, in another aspect, the invention provides a method for cleaning contaminated chip surfaces including directing a plasma-activated radical-enriched gas flow at substantially ambient atmospheric conditions to a contaminated chip surface. The plasma-activated radical-enriched gas both removes molecular contaminants from the contaminated chip surface resulting in a clean hydrophilic chip surface and also passivates the clean chip surface. The molecular contaminants comprise silicone and/or hydrocarbons.

### BRIEF DESCRIPTION OF THE DRAWINGS

Referring to the figures, wherein like numerals represent like parts throughout the several views:

FIG. 1A depicts a 3D integrated semiconductor package;

FIG. 1B depicts schematically a simple chip-handling flow for Die-to-Wafer (D2W) direct hybrid bonding;

FIG. 2 depicts schematically die contamination from an adhesive film;

FIG. 3 depicts schematically D2W bond strength reduction due to contamination;

FIG. 4 depicts schematically D2W bond strength without contamination;

FIG. 5 depicts schematically a simple chip-handling flow with an atmospheric plasma cleaning step;

FIG. 6 depicts an atmospheric plasma cleaning system;

FIG. 7 depicts the components of the atmospheric plasma system of FIG. 6;

FIG. 8 depicts the cleaning treatment of a die with the atmospheric plasma system of FIG. 6;

FIG. 9A depicts the ONTOS Equipment Systems atmospheric plasma system;

FIG. 9B depicts the wafer treatment area A in the atmospheric plasma system of FIG. 9A;

FIG. 10 depicts the process gas mixing network of the atmospheric pressure plasma system of FIG. 9A;

FIG. 11 depicts the process of testing the efficacy of the chip cleaning with the atmospheric plasma system of FIG. 9A;

FIG. 12 depicts water contact angle (WCA) surface metrology results for a chip contaminated by Gel-Pak 4 before and after cleaning with the atmospheric plasma system of FIG. 9A;

FIG. 13 depicts Fourier Transform Infrared (FTIR) results for a chip contaminated with Gel-Pak 4 before and after cleaning with the atmospheric plasma system of FIG. 9A;

FIG. 14 depicts WCA surface metrology results for a chip contaminated with Gel-Pak 8 before and after cleaning with the atmospheric plasma system of FIG. 9A;

FIG. 15 depicts FTIR results for a chip contaminated with Gel-Pak 8 before and after cleaning with the atmospheric plasma system of FIG. 9A;

FIG. 16 depicts WCA surface metrology results for a chip contaminated with blue dicing tape before and after cleaning with the atmospheric plasma system of FIG. 9A;

FIG. 17 depicts FTIR results for a chip contaminated with blue dicing tape before and after cleaning with the atmospheric plasma system of FIG. 9A;

FIG. 18 depicts WCA surface metrology results for a chip contaminated with UV dicing tape before and after cleaning with the atmospheric plasma system of FIG. 9A;

FIG. 19 depicts FTIR results for a chip contaminated with UV dicing tape before and after cleaning with the atmospheric plasma system of FIG. 9A;

FIG. 20 graphically depicts the bond strength before and after cleaning with the atmospheric plasma system of FIG. 9A with different gas mixtures; and

FIG. 21 depicts bond breakage test of bonded chips before and after cleaning with the atmospheric plasma system of FIG. 9A.

### DETAILED DESCRIPTION OF THE INVENTION

The present invention relates to a system and a method for cleaning silicon hydrocarbon contact residue from chip surfaces using atmospheric plasma.

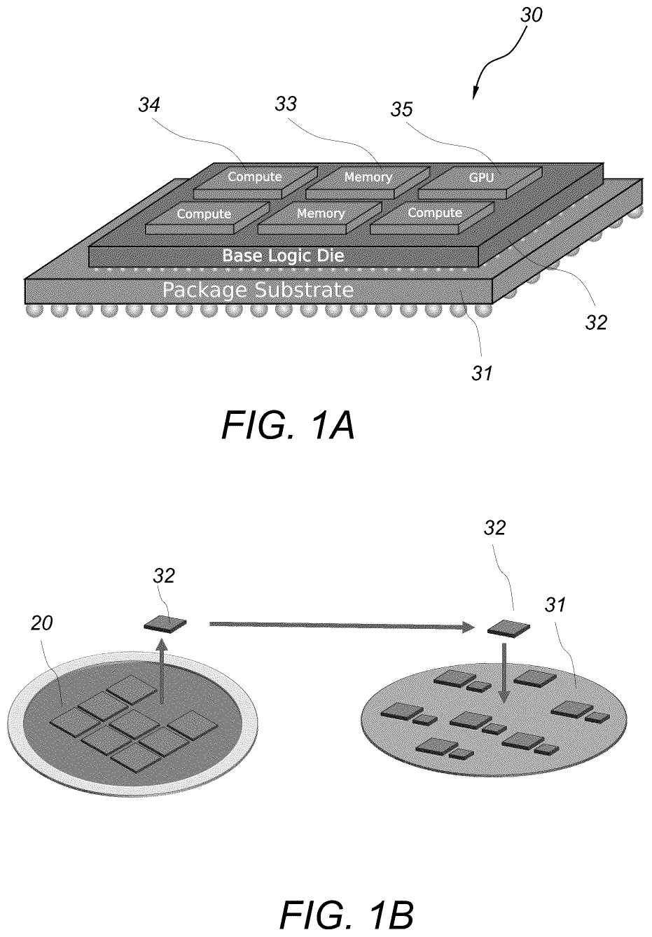

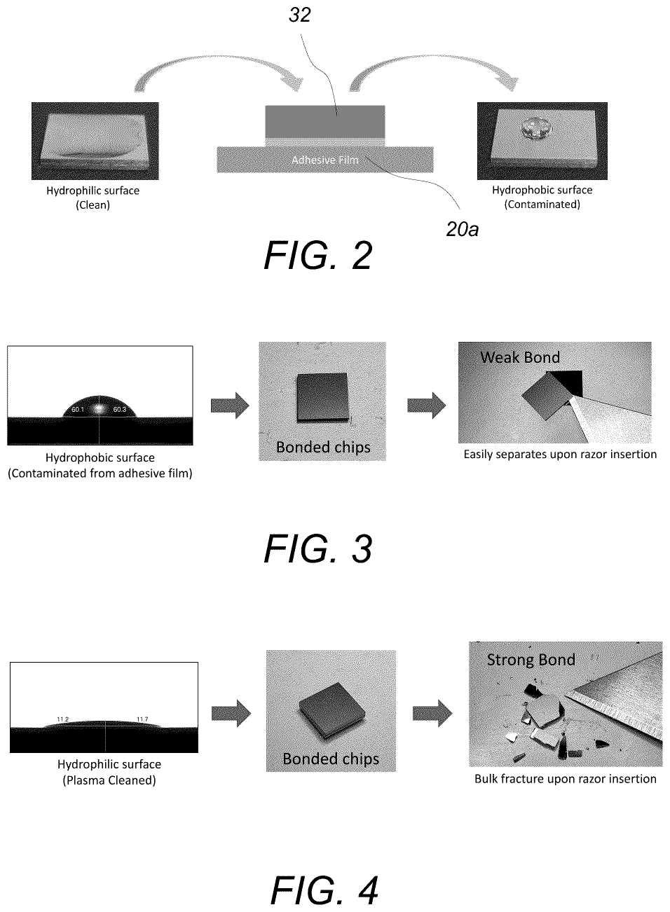

A simple chip-handling flow for die-to-wafer (D2W) direct hybrid bonding involves removing singulated chips 32 from a dicing film 20 or a silicone wafer holder (e.g., Gel pack) and moving them onto a wafer 31 where they are direct bonded for heterogeneous integrations, as shown in FIG. 1B. The method allows for room temperature bonding of several dies and then batch annealing of the bonded components. A singulated chip is a chip (or die) that is separated from a finished wafer of semiconductor. Each singulated chip contains specialized functionalities such as logic, memory, or photonics properties, and is strategically integrated onto a target wafer via D2W direct hybrid bonding. The singulation process occurs by dicing the wafer via scribing and breaking, sawing, or laser cutting. During the dicing process the wafer is mounted on a dicing film 20, which has a sticky adhesive film 20a that holds the wafer on a thin sheet metal frame. Chips 32 face down on the dicing film 20 and the bonding surface of the chips becomes contaminated with residue from the adhesive film 20a of the dicing film. Although, there is no visible residue, there is contamination at a molecular level, which causes the chip bonding surface to become hydrophobic, as indicated in FIG. 2. Similarly, chips 32 that are supported on a Gel-pack or any other vacuum adsorption membrane box have bonding surfaces that are contaminated at a molecular level. Chips 32 that have hydrophobic/contaminated bonding surfaces form a weak bond with the substrate and are easily separated from the substrate with the help of a razor, as shown in FIG. 3. Chips 32 that have hydrophilic/clean bonding surfaces form a strong bond with the substrate and suffer a bulk fracture upon insertion of a razor, as shown in FIG. 3.

Common methods for cleaning the contact residue include solvent cleaning and vacuum plasma treatment.

The present invention provides a method of cleaning and activating the bonding surface of a chip with an atmospheric plasma system. The atmospheric plasma system is capable of operating without a vacuum chamber under atmospheric conditions. Because an atmospheric plasma system is more compact, and can operate on-demand, it can be installed directly inline within production bonding equipment for potential benefits including reduced cost and greater effectiveness, simplicity, and speed.

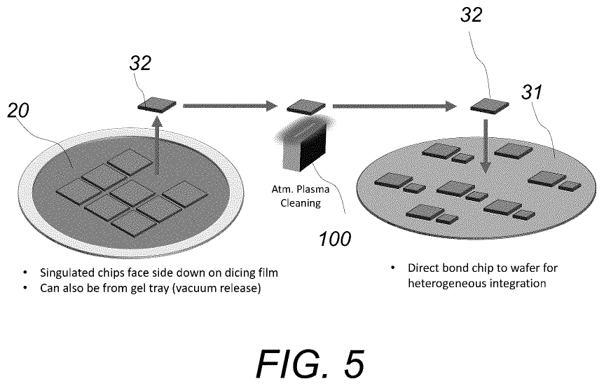

Referring to FIG. 5, a simple chip-handling flow for die-to-wafer (D2W) direct hybrid bonding with an atmospheric plasma clean step involves removing singulated chips 32 from a dicing film 20 or silicone membranes (Gel-pack) and passing them through an atmospheric plasma system 100, prior to moving them onto a wafer 31 where they are direct bonded for heterogeneous integration.

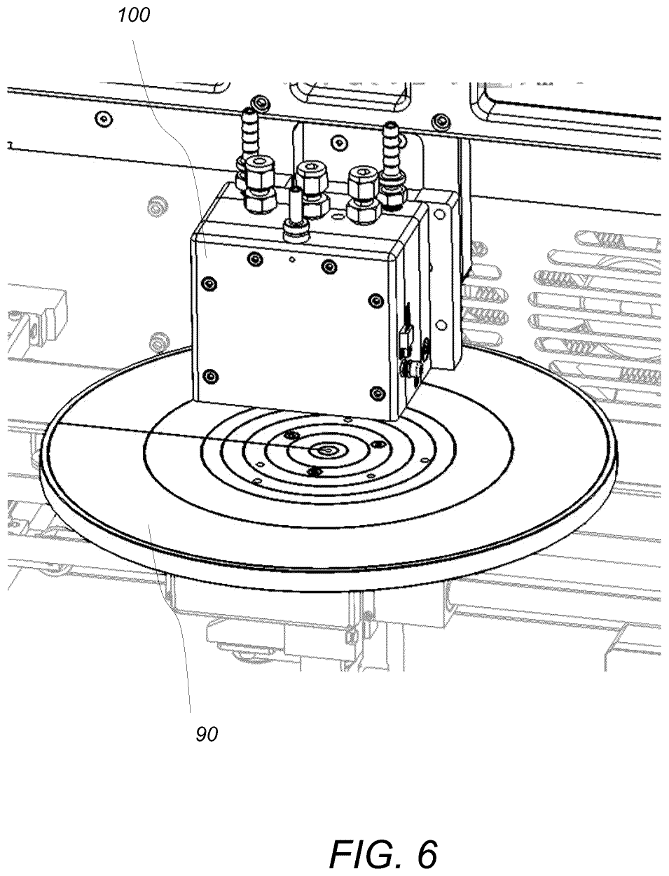

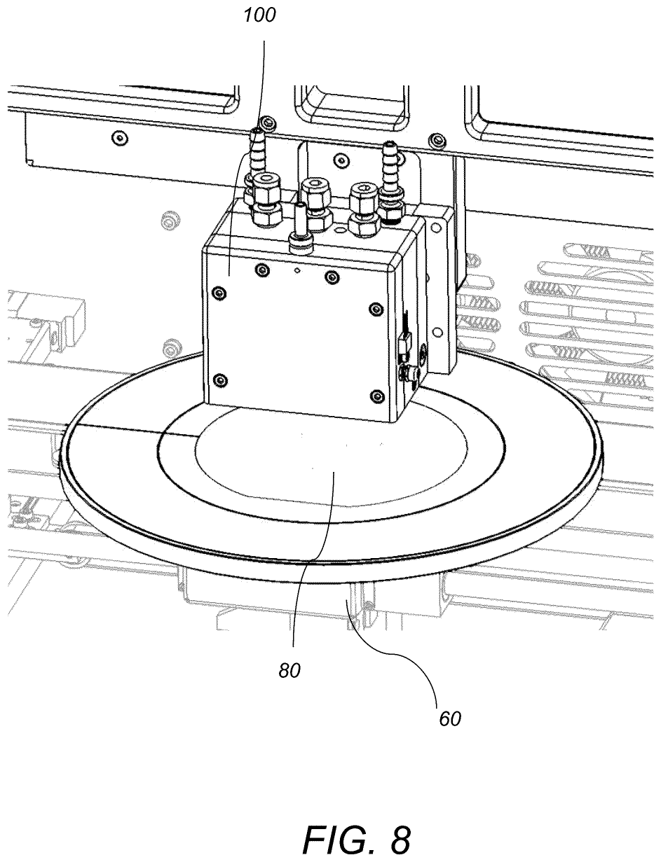

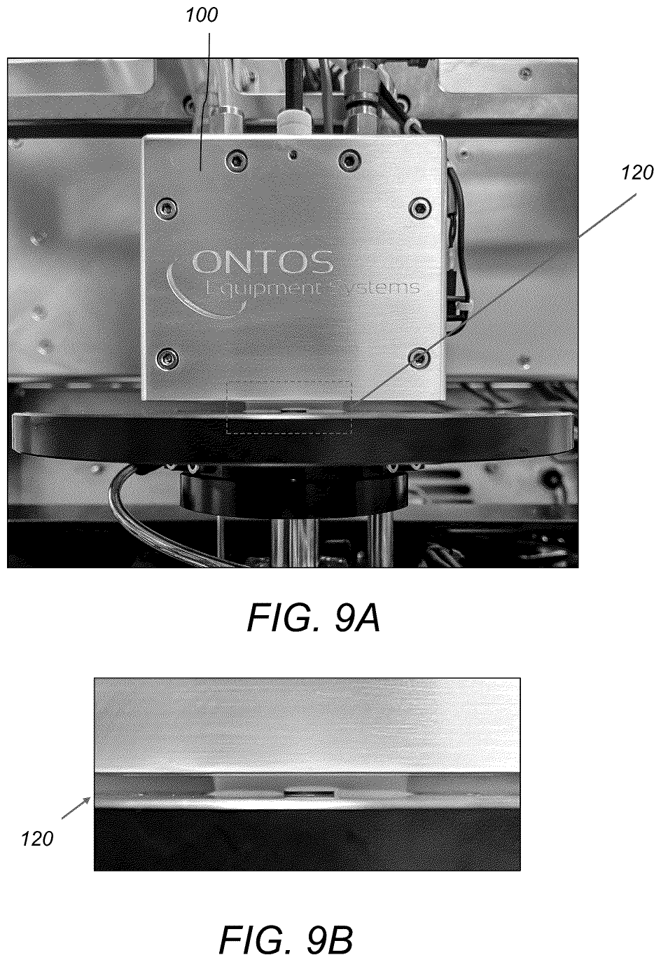

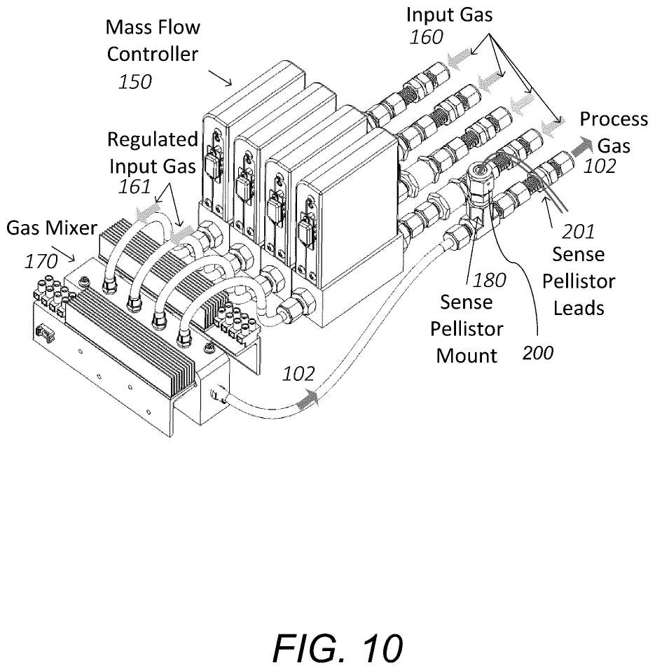

Examples of atmospheric pressure plasma systems 100 for surface preparation include the Ontos 7 and OntosTT, manufactured by ONTOS Equipment Systems, LLC, Chester, NH 03036, USA. OntosTT is shown in FIG. 6-FIG. 10. Ontos 7 is described in U.S. patent application Ser. No. 15/797,017 filed on Oct. 30, 2017, now U.S. Pat. No.: 10,672,594 B2 issued Jun. 2, 2020, and entitled SYSTEM AND METHOD FOR PLASMA HEAD THERMAL CONTROL, which is commonly assigned and the contents of which are expressly incorporated herein by reference. Both Ontos 7 and OntosTT include a uniquely-designed atmospheric plasma source 100 with a 10 mm to 110 mm-wide process zone 90, shown in FIG. 6. Substrates 80 with diameters from 2 mm up to 300 mm are supported on a computer controlled X-Y-Z stage 60, as shown in FIG. 8. OntosTT plasma source ignites a plasma at specific local areas or the surface of the substrate 80.

Referring to FIG. 6-FIG. 10, the atmospheric plasma head of plasma system 100 includes a process gas inlet 102, a gas passage with a dielectric liner 104, an RF electrode 106 and a ground electrode 108. RF electrode 106 and ground electrode 108 are arranged at opposite sides of a segment 107 of the gas passage 104. Gas enters the passage with the dielectric liner 104 through inlet 102 and passes through segment 107. Between the two electrodes 106, 108 in segment 107, a glow discharge-type plasma is generated via an RF power source 101. The plasma is completely contained within the plasma head of system 100. The plasma exits the gas passage via a slit 112 and enters a process zone area 120 immediately above the substrate 80. Laminar flow of the plasma gas in the process zone area 120 excludes the atmosphere from the process zone area 120 and thus vacuum is not needed. The activated plasma gas in the process zone area 120 is a cool gas with a temperature lower than 100° C. and does not include ions or hot electrons. The electrodes are driven via RF power of 30 W to 600 W at 13.56 MHz. In one example, the plasma output slit 112 has a length in the range of 10 mm to 50 mm.

Referring to FIG. 10, four mass flow channels 160 deliver precise digital control of a non-toxic gas mix 102 to the plasma head of system 100. Each gas flow channel includes a mass flow controller 150 that provides regulated input gas 161 to a gas mixer 170. Gas mixer 170 mixes the regulated input gases 161 and provides the gas mix 102. At least one helium mass flow channel is required as the dominant species carrier gas is helium at a concentration of more than 95% by volume. The dielectric properties and reactive properties of helium make it the ideal carrier gas. In addition to helium, other gasses may be added for chemical enhancement of the substrate 80 surface treatment. Examples of additional gasses used include nitrogen (N2), oxygen (O2), Argon (Ar), helium hydrogen (HeH2) mix, among others. The helium concentration in the process gas mix 102 is measured with a pellistor sensor 200 that is mounted on the pellistor mount 180 that is in line with the process gas mix 102. The pellistor mount 180 is located anywhere along the process gas 102 path between the gas mixer 170 and the plasma head 100. A pellistor sensor 200 is a device used to detect and measure helium concentration in a gas that has a different thermal conductivity compared to air.

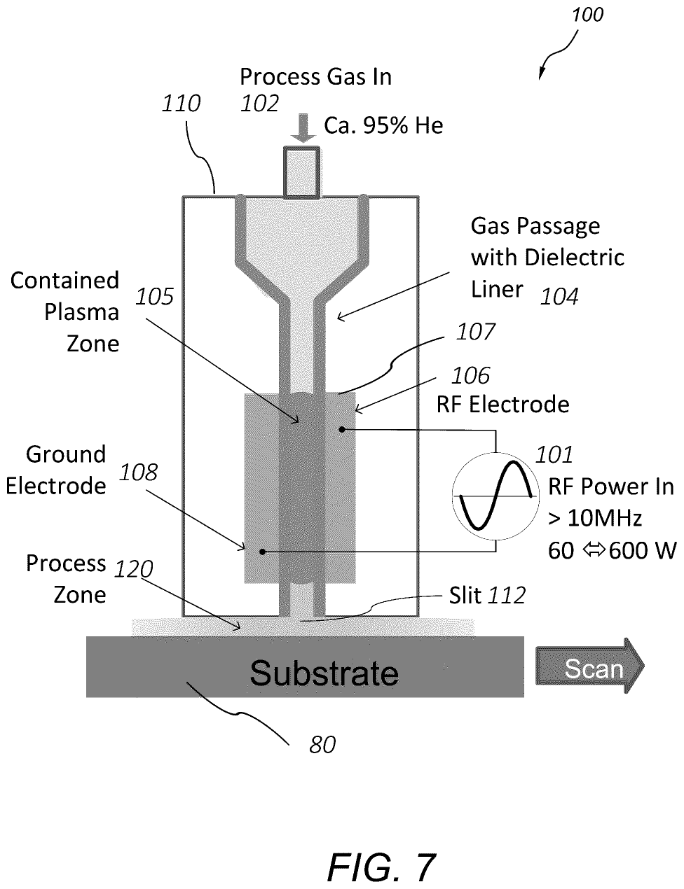

Referring to FIG. 7, plasma is formed when sufficient helium concentration flows in the gas passage 104, and RF Power 101 is applied between the RF electrodes 106 108. The time when RF Power is first applied, is known as plasma ignition time. Electrically, the helium acts as a dielectric medium between the RF electrodes, acting as a power capacitor. The atmospheric plasma creates H*, N*, O* chemical species (radicals) that are used to clean, and activate the surfaces prior to bonding. The atmospheric plasma is also used to passivate metallic contacts on the chip, as described in co-pending U.S. nonprovisional application Ser. No. 17/085,786 filed on Oct. 30, 2020 and entitled “THERMOCOMPRESSION BONDING WITH PASSIVATED TIN-BASED CONTACTING METAL”, which is commonly assigned and the contents of which are expressly incorporated herein by reference. Passivation of contacts with the atmospheric plasma is also described in U.S. Pat. No. 8,567,658 B2 issued Oct. 29, 2013 and entitled “Method of plasma preparation of metallic contacts to enhance mechanical and electrical integrity of subsequent interconnect bonds”, which is commonly assigned and the contents of which are expressly incorporated herein by reference. The system is designed to be ultra clean and safe for sensitive electronic devices.

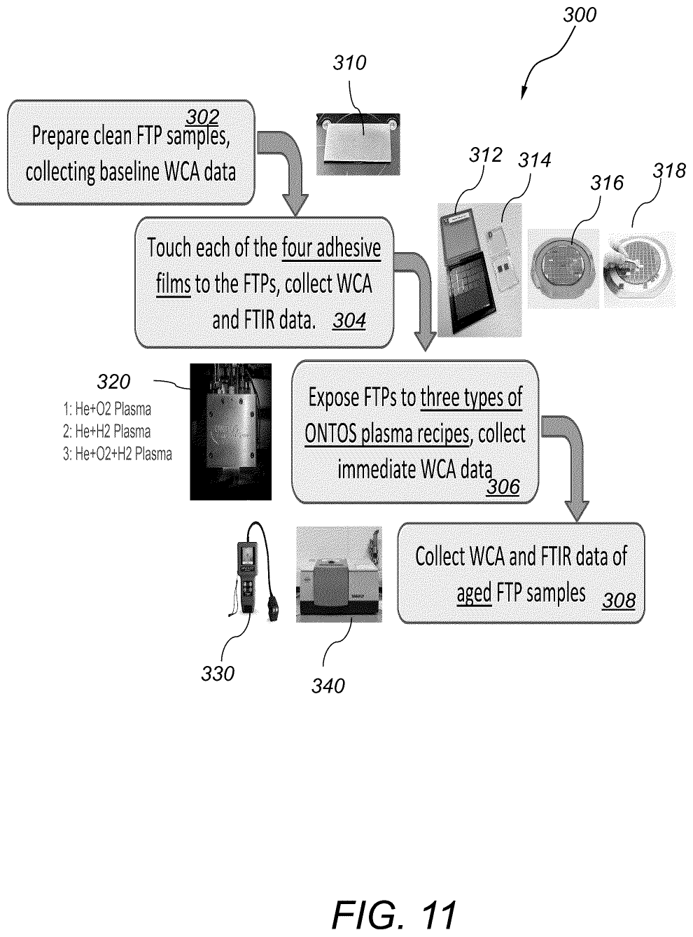

Referring to FIG. 11, the method 300 of cleaning and activating the bonding surface of a chip with the atmospheric plasma system 100 was tested with the following experimental procedure. First, test coupons 310 were prepared and baseline surface metrology data were collected, including water contact angle goniometry and Fourier transform infrared spectroscopy (302). Test coupons 310 are ferrotype plates (FTPs). In one example plates 310 are chrome coated steel plates having dimensions 25 mm×50 mm. These plates 310 were selected because they are inexpensive and work well with the selected surface metrology techniques. The surface metrology techniques that are used to analyze contact residue include water contact angle goniometry (WCA) 330 in a top-down image acquisition mode and Fourier transform infrared spectroscopy (FTIR) 340. WCA is used because it is sensitive to molecular surface changes and FTIR is used for identifying the chemical composition of the residue. Next, four FTPs 310 were touched by four different adhesive films, respectively and then surface metrology WCA and FTIR data were collected (304). The four different type of adhesives include silicone membrane with tack level 4 (Gel-Pak 4 ), 312, silicone membrane with tack level 8 (Gel-Pak 8), 314, blue dicing tape 316, and UV release dicing tape 318. These materials were chosen because of their common use in wafer and chip-scale processing. Prior to contact, the FTP samples were cleaned using a solvent wipe followed by flame treatment. Next, the surfaces of the contaminated FTPs 310 were exposed to three types of atmospheric plasma recipes 320 and then surface metrology data were collected (306). The three different atmospheric plasma recipes 320 include He+O2 plasma (Sample 1), He+H2 plasma (Sample 2), and He+O2+H2 plasma (Sample 3). The samples were then aged and then surface metrology data were collected of the aged samples (308). In one example, the He+O2 plasma recipe includes the following conditions: He 17.82 standard liter per minute (slpm), O2 0.18 slpm, Power 200 W, Gap 1 mm, Scan Speed 1 mm/s. In one example, the He+H2 plasma recipe includes the following conditions: He 13.20 slpm, 5% H2+95% He 3.3 slpm, Power 200 W, Gap 1 mm, Scan Speed 1 mm/s. In one example, the He+H2+O2 plasma recipe includes the following conditions: He 13.56 slpm, 5% H2/95% He 6.4 slpm, 02 0.04 slpm, Power 200 W, Gap 2 mm, Scan Speed 1 mm/s.

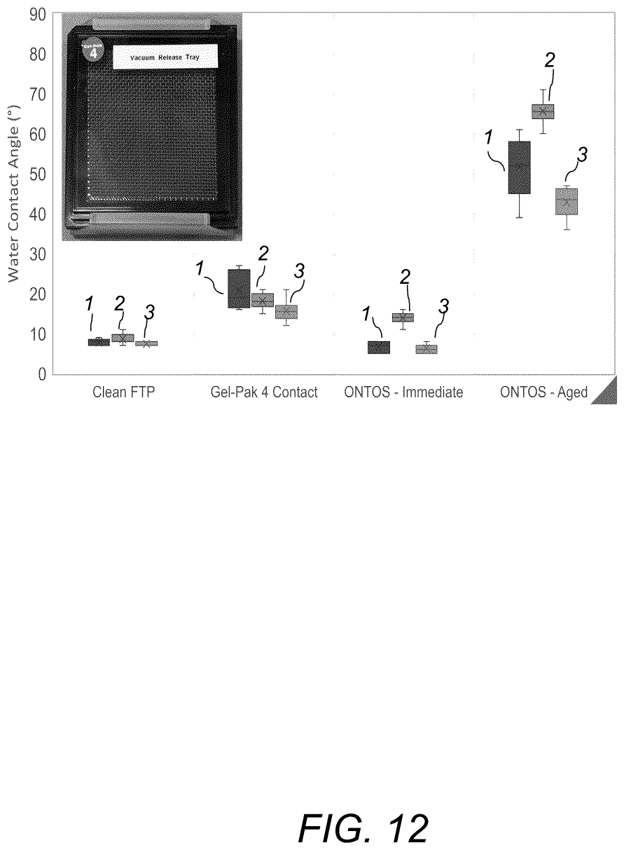

Referring to FIG. 12, water contact angle measurement results are plotted for three different samples. Sample 1 was treated with He+O2 plasma, Sample 2 was treated with He+H2 plasma, and Sample 3 was treated with He+O2+H2 plasma. The plots depict the results for clean FTPs, after contact with Gel-Pak 4, immediately after treatment with the atmospheric plasma system and after aging for 3 days after the atmospheric plasma treatment. As was mentioned above, water contact angle (WCA) is used to measure the hydrophilicity and surface energy of a surface. Lower contact angle, which is indicative of a high surface energy, is generally correlated with improved bond strength. The low WCA of 9° for the three FTP samples prepared for this experiment confirms that the initial cleaning works as expected. However, after touching the surface of the three FTP samples with the Gel-Pak 4 silicone membrane, we see a significant rise in WCA now measuring up to 25°. Clearly, some amount of contact residue has transferred to the FTP, which can reduce the wetting and decrease surface energy. Following the contact with Gel-Pak 4, each of the three samples were exposed to an atmospheric plasma with different process gas recipes. Sample 1 was exposed to an atmospheric plasma containing He+O2 gases. The resulting WCA is brought back down to the initial 9°, indicating a good cleaning effect. This was expected since oxygen is the typical gas used in vacuum plasma systems. Sample 2 was exposed to He+H2 atmospheric plasma and shows a mild reduction in WCA to about 14°, which indicates only a partial reduction of surface contaminates or slight increase in surface energy. Sample 3 was exposed to He+O2+H2atmospheric plasma and shows similar WCA reduction as Sample 1 bringing the WCA back down to 9°. The samples were then aged approximately 3 days and the WCA measured again. All three samples show an unexpected large rise in WCA with Sample 2 showing the largest WCA of 65°. It is thought that perhaps these samples were re-contaminated by using the same foil used to wrap the contaminated samples. In summary, it is shown that contact with Gel-Pak 4 increased the contact angle by 5°-10° degrees. It is also shown, that the contact angle was reduced by 5°-15° degrees after treatment with the atmospheric plasma system for all three samples. Aging of the samples for 3 days after the treatment with the atmospheric plasma system increased the contact angle by 40°-50° degrees.

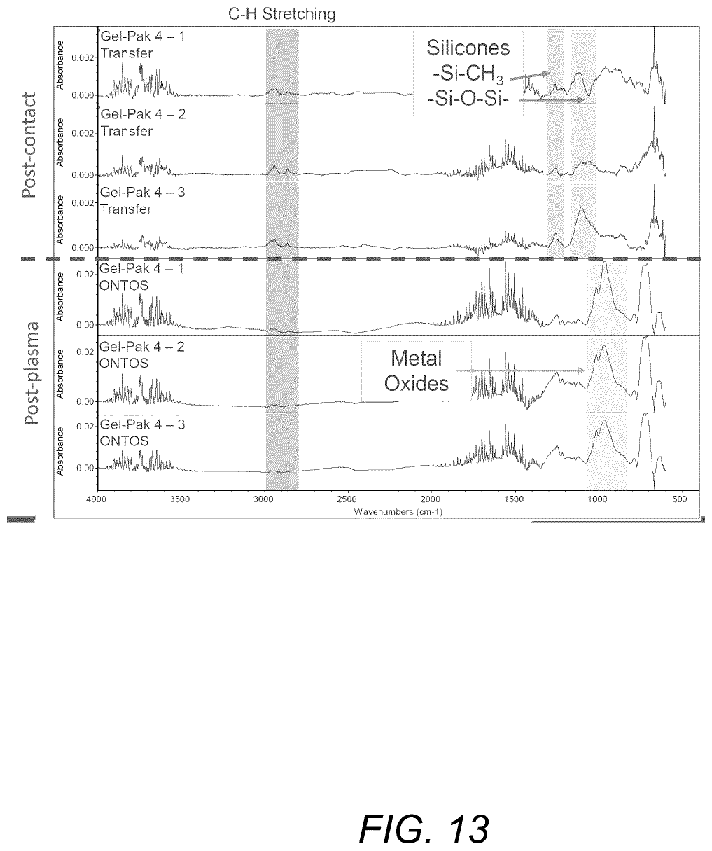

Referring to FIG. 13, FTIR absorbance spectroscopy results indicate the presence of hydrocarbons (C—H stretching) and silicones on all samples after contact with the Gel-Pak 4. The FTIR absorbance spectroscopy results also indicate that the hydrocarbons (C—H stretching) and silicone peaks are significantly reduced or eliminated after the treatment with the atmospheric plasma system. The FTIR absorbance spectroscopy results also indicate the presence of metal oxides after aging in an oxygen environment. It is thought that this metal oxidation is due to oxidation processes during plasma treatment (especially oxygen-containing plasmas), aging in an atmospheric air environment, or perhaps transformation of the silicone groups into silica (SiO2).

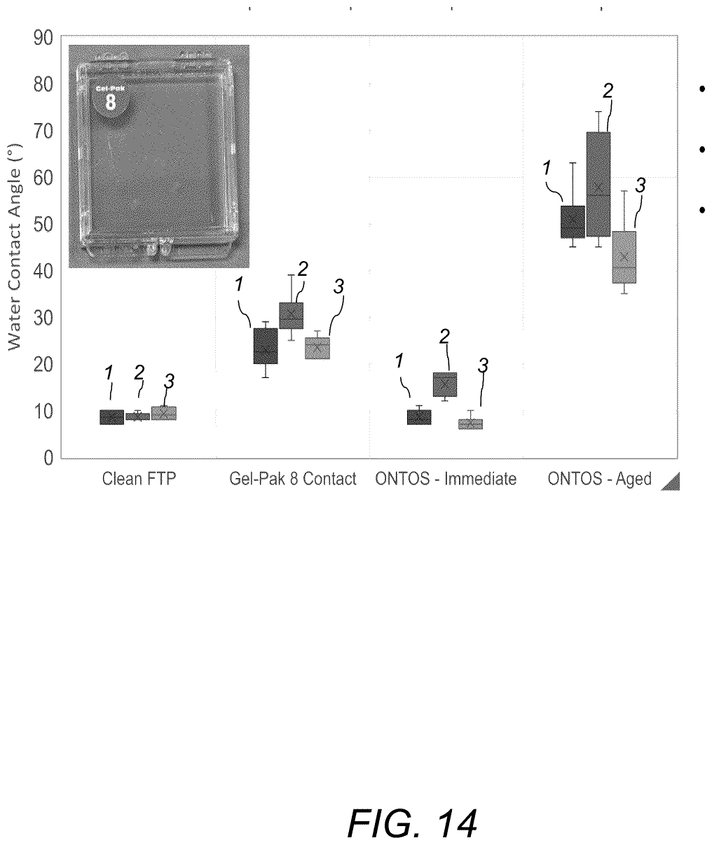

Referring to FIG. 14, water contact angle measurement results are plotted for three different samples. Sample 1 was treated with He+O2 plasma, Sample 2 was treated with He+H2 plasma, and Sample 3 was treated with He+O2+H2 plasma. The plots depict the results for clean FTPs, after contact with Gel-Pak 8, immediately after treatment with the atmospheric plasma system and after aging after the atmospheric plasma treatment. It is shown that contact with Gel-Pak 8 increased the contact angle by 10°-20° degrees. It is also shown, that the contact angle was reduced by 10°-15° degrees after treatment with the atmospheric plasma system for all three samples. Aging of the samples for 3 days after the treatment with the atmospheric plasma system increased the contact angle by 30°-40° degrees.

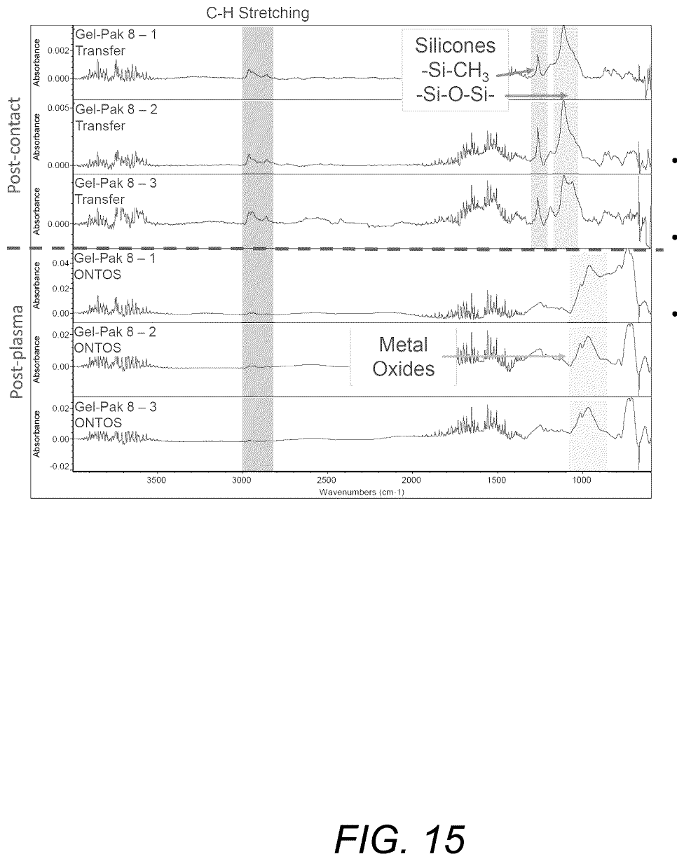

Referring to FIG. 15, FTIR absorbance spectroscopy results indicate the presence of hydrocarbons (C—H stretching) and silicones on all samples after contact with the Gel-Pak 8. The FTIR absorbance spectroscopy results also indicate that the hydrocarbons (C—H stretching) and silicone peaks are significantly reduced or eliminated after the treatment with the atmospheric plasma system. The FTIR absorbance spectroscopy results also indicate the presence of metal oxides after aging in an oxygen environment.

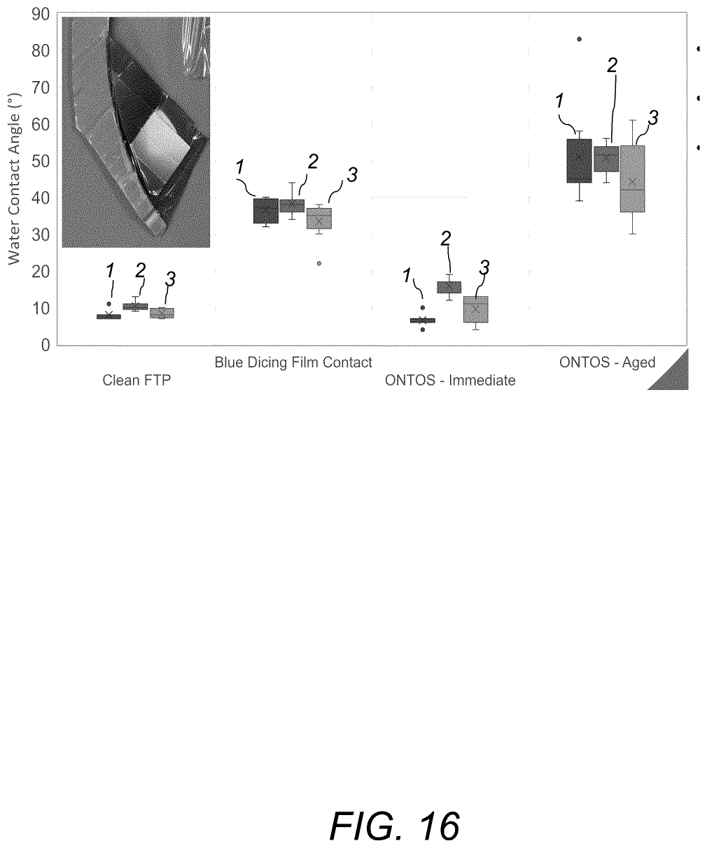

Referring to FIG. 16, water contact angle measurement results are plotted for three different samples. Sample 1 was treated with He+O2 plasma, Sample 2 was treated with He+H2 plasma, and Sample 3 was treated with He+O2+H2 plasma. The plots depict the results for clean FTPs, after contact with blue dicing tape, immediately after treatment with the atmospheric plasma system and after aging after the atmospheric plasma treatment. It is shown that contact with blue dicing tape increased the contact angle by 20°-30° degrees. It is also shown, that the contact angle was reduced by 20°-30° degrees after treatment with the atmospheric plasma system for all three samples. Aging of the samples after the treatment with the atmospheric plasma system increased the contact angle by 20°-40° degrees.

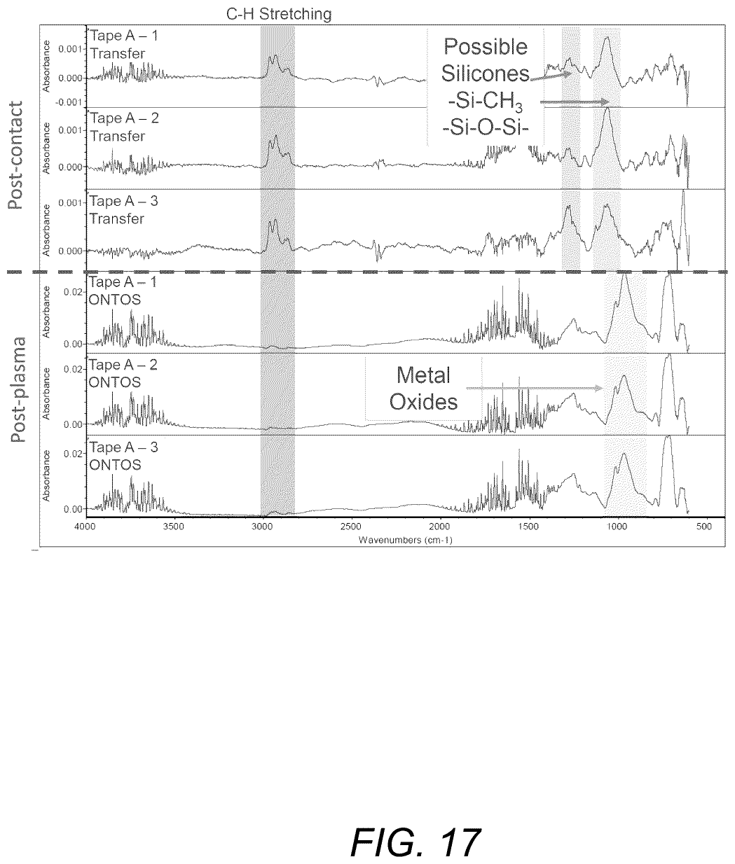

Referring to FIG. 17, FTIR absorbance spectroscopy results indicate the presence of hydrocarbons (C—H stretching) and silicones on all samples after contact with the blue dicing tape. The FTIR absorbance spectroscopy results also indicate that the hydrocarbons (C—H stretching) and silicone peaks are significantly reduced or eliminated after the treatment with the atmospheric plasma system. The FTIR absorbance spectroscopy results also indicate the presence of metal oxides after aging in an oxygen environment.

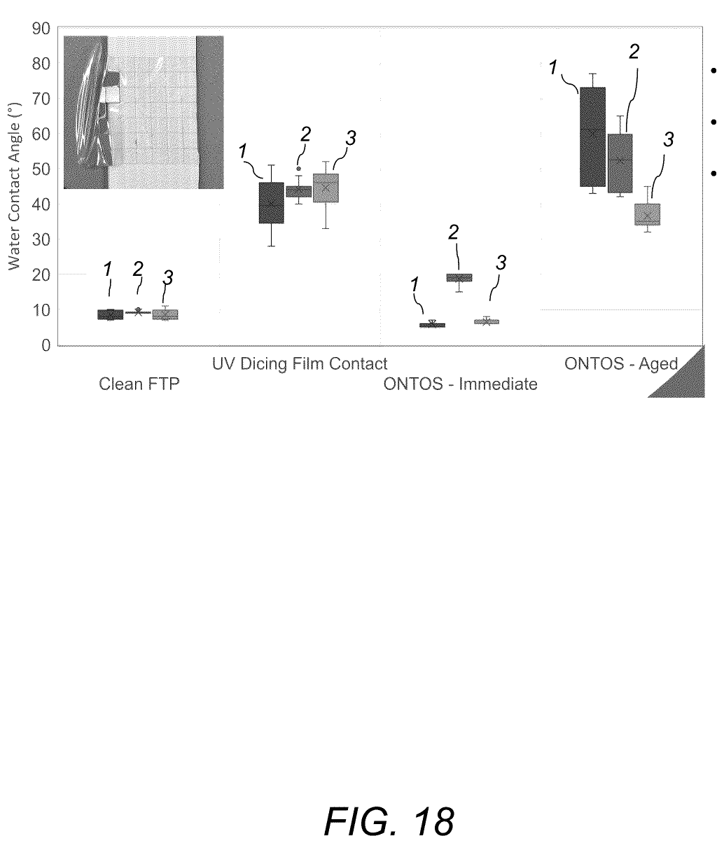

Referring to FIG. 18, water contact angle measurement results are plotted for three different samples. Sample 1 was treated with He+O2 plasma, Sample 2 was treated with He+H2 plasma, and Sample 3 was treated with He+O2+H2 plasma. The plots depict the results for clean FTPs, after contact with UV dicing tape, immediately after treatment with the atmospheric plasma system and after aging after the atmospheric plasma treatment. It is shown that contact with UV dicing tape increased the contact angle by 25°-40° degrees. It is also shown, that the contact angle was reduced by 20°-35° degrees after treatment with the atmospheric plasma system for all three samples. Aging of the samples after the treatment with the atmospheric plasma system increased the contact angle by 25°-60° degrees.

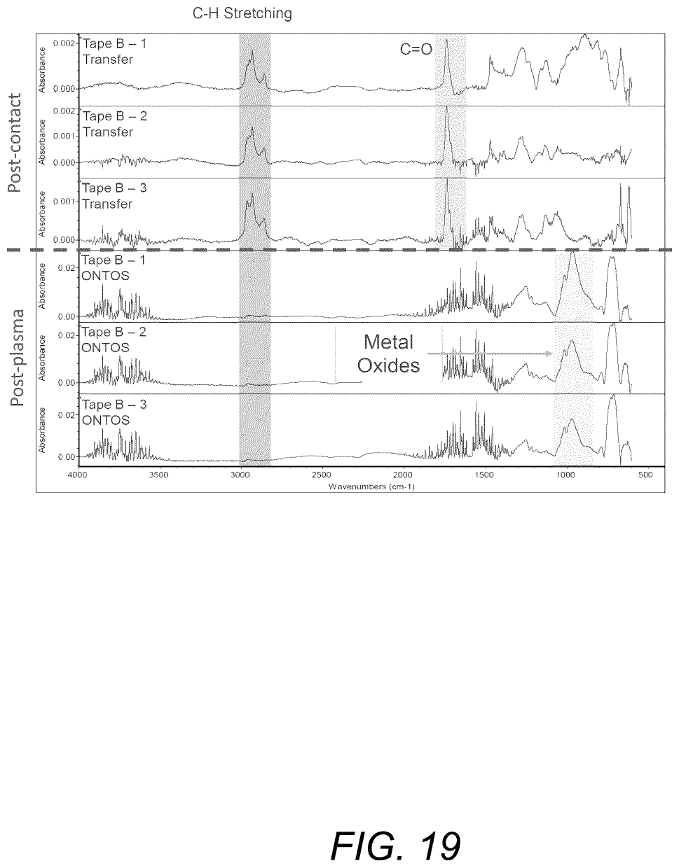

Referring to FIG. 19, FTIR absorbance spectroscopy results indicate the presence of hydrocarbon (C—H stretching), carbonyl, and silicones on all samples after contact with the UV dicing tape. The FTIR absorbance spectroscopy results also indicate that the hydrocarbons (C—H stretching), carbonyl, and silicone peaks are significantly reduced or eliminated after the treatment with the atmospheric plasma system. The FTIR absorbance spectroscopy results also indicate the presence of metal oxides after aging in an oxygen environment.

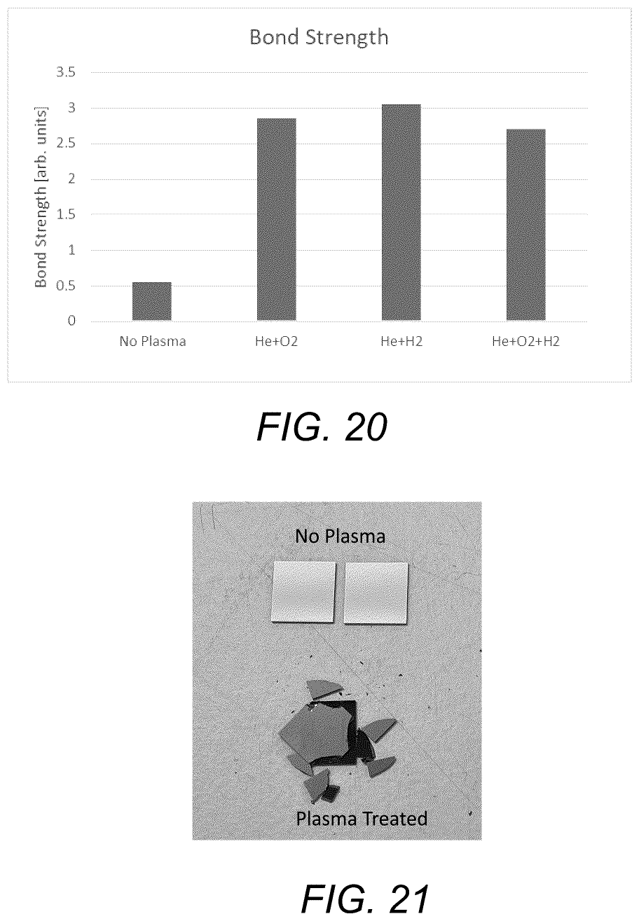

Contaminated SiO2 samples were treated with the atmospheric plasma system and then were direct bonded and the bond strength was tested. The bond strength was tested by separating them. Referring to FIG. 20, the bond strength (in arbitrary units) is depicted for contaminated samples without prior plasma treatment, for samples treated with He+O2 atmospheric plasma, for samples treated with He+H2 atmospheric plasma, and for samples treated with He+O2+H2 atmospheric plasma. It is shown that the contaminated samples without prior plasma treatment separated with little force, whereas samples cleaned with the atmospheric plasma system broke before delamination, as shown in FIG. 21. The bond strength of the cleaned samples is at least 5-6 times stronger than the not treated contaminated sample.

Several embodiments of the present invention have been described. Nevertheless, it will be understood that various modifications may be made without departing from the spirit and scope of the invention. Accordingly, other embodiments are within the scope of the following claims.

What is claimed is:

1. A method of die-to-wafer (D2W) direct hybrid bonding, comprising the steps of:
a) removing a singulated die from a support frame wherein said singulated die is held onto the support frame via an adhesive film or silicone membrane and wherein a bonding surface of the singulated die is contaminated at a molecular level by said adhesive film or silicone membrane;
b) directing plasma-activated radical-enriched gas flow at substantially ambient atmospheric conditions to said contaminated bonding surface of the singulated die, wherein said plasma-activated radical-enriched gas both removes molecular contaminants from said contaminated bonding surface resulting in a clean bonding surface and also passivates said clean bonding surface;
c) directly bonding said clean bonding surface of said singulated die onto a wafer for heterogeneous integration.

2. The method of claim 1, wherein said molecular contaminants comprise hydrocarbons.

3. The method of claim 1, wherein said molecular contaminants comprise silicones.

4. The method of claim 1, wherein said plasma-activated radical-enriched gas comprises He and O₂ plasma.

5. The method of claim 1, wherein said plasma-activated radical-enriched gas comprises He and H₂ plasma.

6. The method of claim 1, wherein said plasma-activated radical-enriched gas comprises He and O₂ and H₂ plasma.

7. The method of claim 1, wherein said plasma-activated radical-enriched gas comprises argon (Ar) plasma.

8. The method of claim 1, wherein said plasma-activated radical-enriched gas comprises one of helium (He), nitrogen (N2), oxygen (O2), Argon (Ar), helium hydrogen (HeH2) mix or mixtures thereof.

9. The method of claim 1, wherein said adhesive film comprises one of dicing tape, or UV dicing tape.

10. The method of claim 1, wherein said silicone membrane comprises one of silicone membrane with tack level 4, or silicone membrane with tack level 8.

11. The method of claim 1, further comprising measuring hydrophilicity and surface energy of the bonding surface via water contact angle (WCA).

12. The method of claim 1, further comprising measuring and identifying said molecular contaminants via Fourier transform infrared spectroscopy (FTIR).

13. A method for cleaning contaminated chip surfaces comprising:
directing a plasma-activated radical-enriched gas flow at substantially ambient atmospheric conditions to a contaminated chip surface, wherein said plasma-activated radical-enriched gas both removes molecular contaminants from said contaminated chip surface resulting in a clean hydrophilic chip surface and also passivates said clean chip surface;
wherein said molecular contaminants comprise silicone and/or hydrocarbons.

14. The method of claim 13, wherein said plasma-activated radical-enriched gas comprises He and O₂ plasma.

15. The method of claim 13, wherein said plasma-activated radical-enriched gas comprises He and H₂ plasma.

16. The method of claim 13, wherein said plasma-activated radical-enriched gas comprises He and O₂ and H₂ plasma.

17. The method of claim 13, wherein said plasma-activated radical-enriched gas comprises one of helium (He), nitrogen (N2), oxygen (O2), Argon (Ar), helium hydrogen (HeH2) mix or mixtures thereof.

18. A system that implements the method of claim 1.
